(19) United States
(12) Patent Application Publication
(10) Pub. No.: US 2006/0138411 A1
(43) Pub. Date: Jun. 29, 2006

(54) Semiconductor wafer with a test structure, and method

(76) Inventors: Susanne Lachenmann, Muenchen (DE); Valentin Rosskopf, Poettmes (DE); Sibina Sukman-Praehofer, Muenchen (DE); Ramona Winter, Muenchen (DE)

Correspondence Address: SLATER & MATSIL LLP, 17950 PRESTON ROAD, SUITE 1000, DALLAS, TX, 75252, US

(21) Appl. No.: 11/293,031

(22) Filed: Dec. 2, 2005

(30) Foreign Application Priority Data
Dec. 3, 2004 (DE) 10 2004 058 411.7

(51) Int. Cl. H01L 21/66; H01L 23/58

(52) U.S. Cl. 257/48; 438/14

(57) ABSTRACT

The invention proposes a semiconductor wafer with a test structure for detecting parasitic contact structures on the semiconductor wafer, in which a first interconnect plane (A) contains interconnects (1) running parallel to one another and a second interconnect (2) that is arranged between the latter. The two first interconnects (1) are connected by means of contact elements (4) arranged above them, to a third interconnect (3) that runs in a second interconnect plane (B) transverse to the first and second interconnects, and that also crosses the second interconnect (2). If there is a parasitic contact structure (5) formed between the contact elements (4), which has arisen during the lithographic exposure for producing the contact elements (4) on account of constructively interfering diffraction maxima, then this shorts the second interconnect (2) to the third interconnect (3). This results in a leakage current path perpendicular to the substrate surface (10a), the path extending from the second (2) to the third (3) interconnect even in the case of very narrow parasitic contact structures (5). When test needles are placed in contact with the second and third interconnects, an electrical measurement allows the extent of a parasitic contact structure (5) to be detected with a particularly high level of probability.

This application claims priority to German Patent Application 10 2004 058 411.7, which was filed Dec. 3, 2004, and is incorporated herein by reference.

### TECHNICAL FIELD

The invention relates to a semiconductor wafer with a test structure and to a method for detecting parasitic contact structures on a semiconductor wafer with a test structure.

### BACKGROUND

In semiconductor fabrication, semiconductor wafers are subjected to a large number of processing steps in order to produce on them a large number of integrated semiconductor circuits of the same type for semiconductor chips. When the integrated semiconductor circuits are complete, a semiconductor wafer is split into a large number of semiconductor chips. This operation involves the semiconductor wafer being sawn up along edge areas, which are arranged between adjacent semiconductor circuits. The edge areas form the saw frame (“kerf”), which surrounds each integrated semiconductor circuit individually and is destroyed when the semiconductor wafer is split. Following splitting, the semiconductor chips are contact-connected and encapsulated.

In the saw frame that is arranged between the integrated semiconductor circuits, test structures are frequently produced that can be used to perform electrical function tests before the semiconductor wafer has been split. Such test structures can be used to test those semiconductor circuits that remain after splitting and that are the actual semiconductor product. By way of example, tests that allow conclusions to be drawn about the quality of the fabricated integrated semiconductor circuit can be performed. However, such tests are not intended as a replacement for electrical function tests in which the information is written to the memory cells in the semiconductor circuits and is read again for test purposes. However, both types of electrical tests can be performed by placing needle cards onto the semiconductor circuits, with additional test needles being arranged above the saw frame and placed onto it in order to actuate test structures electrically.

The test structures in the saw frame may be a reproduction of a memory cell array in integrated memory circuits, in particular. In that case, the test structures have similar structures to the memory cells in a memory cell array and the wiring thereof, but are modified such that electrical measurements can be performed on them that cannot be performed in the memory cell array of the actual memory circuit itself, for example because particular structure elements are covered by other layers and are, therefore, not accessible. By way of example, a test structure arranged in a saw frame region may be provided with electrical connections, which allows resistance measurement, current measurement or determination of leakage current paths that cannot be performed in the actual memory cell array.

Leakage currents within a semiconductor circuit may arise, inter alia, as a result of alignment errors during lithographic exposure. One problem of lithographic exposure is that interference results from simultaneously exposing adjacent structures whose distance from one another is in the region of the optical resolution limit for the wavelength used for lithographic exposure or in the region of the minimum feature size provided for the respective plane of the semiconductor circuit. This may result in further regions of the photoresist layer used as a mask being exposed unintentionally and in removal of the regions of the layer that is to be patterned below it during etching. Intensity maxima situated on the semiconductor product between the depictions of adjacent mask openings in the lithographic mask (“reticle”), which intensity maxima are produced through diffraction, in particular, result (in the subsequent etching process) in contact openings in the layer that is to be patterned in regions that have no correspondence on the lithographic mask. If such openings are produced in a dielectric layer and then a conductive material is deposited in all the etched openings in the dielectric layer, parasitic contact structures are produced, which are in a similar form to the regular standard contacts or vias but are arranged at undesirable positions. The parasitic contact structures cause short circuits if they simultaneously make contact with two interconnects, one of which runs in the interconnect plane above the contact structure and the other of which runs in the interconnect plane below the contact structure. The probability of such chip failures is higher the more pronounced the diffraction-related ancillary maxima between closely adjacent mask openings.

Parasitic contact structures, known as “side lobes”, that arise as a result of diffraction maxima between adjacent standard contacts, can be produced intentionally with relatively great frequency and in more acutely pronounced form in test structures, which are provided specifically for detecting them and which are consciously designed to accept infringements to design rules. In addition, the conductive structures of a test structure can be actuated using test needles in order to establish through electrical measurement whether a plurality of conductive structures are shorted together on account of parasitic side-lobe contacts. This allows detection of the existence of parasitic contact structures in a saw frame. This can be used to draw conclusions regarding the occurrence of corresponding parasitic contacts within the actual memory circuit.

If infringements to design rules are consciously accepted, however, this results in a significant increase in defects in the semiconductor circuits on the wafer. Test structures produced in conflict with design rules are, therefore, disadvantageous. Without infringing design rules, however, parasitic contact structures that are too small to short together conductive structures passing in their surroundings cannot conventionally be detected electrically. There is thus a need for test structures that are designed such that the detection limit for any parasitic contact structures is lowered, specifically as far as possible without infringing the design rules provided for memory circuits arranged on the same semiconductor wafer.

### SUMMARY OF THE INVENTION

In one aspect, the present invention provides a semiconductor wafer having a test structure that can be used to detect parasitic contact structures with a high level of probability during an electrical measurement. The test structure of the semiconductor wafer is intended to be in a form such that parasitic contact structures, if present in the test structure, are surrounded by adjacent conductive structures such that a particularly high level of detection probability and detection frequency is achieved. In another aspect, the present invention provides a method that can be used to detect the existence of parasitic contact structures on a semiconductor wafer in particularly reliable fashion.

In a first embodiment, a semiconductor wafer includes at least two first interconnects, which are arranged in a first interconnect plane and which run parallel to one another at least in sections. At least one second interconnect is arranged in the first interconnect plane between the two first interconnects and runs parallel to the first interconnects. A third interconnect runs in a second interconnect plane is arranged at a greater distance from a surface of the semiconductor wafer than the first interconnect plane. At least one respective contact element is provided on each of the two first interconnects that electrically conductively connects the respective first interconnect to the third interconnect. The distance between the second interconnect and the two first interconnects corresponds to the lithographic resolution limit of the first interconnect plane. In addition, the contact elements are arranged at mirror-inverted positions in relation to the second interconnect running between the first interconnects.

Embodiments of the invention provide a semiconductor wafer having a test structure in which two first interconnects have a second interconnect provided between them, which has at least two contact elements provided above it in mirror-image symmetrical fashion that connect the two first interconnects to one and the same third interconnect. The third interconnect is arranged in a higher-level interconnect plane than the first and second interconnects and routes a contact element on one side of the second interconnect to another contact element, arranged in mirror-image symmetrical fashion with respect thereto, on the opposite side of the second interconnect. The mirror-image symmetry of the inventive arrangement means that parasitic contact structures, which may have been produced on account of interference effects that have arisen during lithographic exposure, are to be expected in a position centrally above the second interconnect, i.e., they make contact with a second interconnect. The contact elements are arranged in mirror-image symmetrical fashion with respect to one another in relation to the second interconnect and connect the two first interconnects to the third interconnect, which is routed away via the region in which parasitic contact structures can be expected to occur.

Any parasitic contact structures that are present are thus routed from the second interconnect to the third interconnect and short the two together. Since the third interconnect is connected to the first interconnects in the first interconnect plane via the two contact elements, a short circuit is obtained between the second line and the two first lines. The parasitic contact structure itself, which sets up this electrical connection, conducts the current from the first interconnect plane to the second interconnect plane, so that even when the parasitic contact structure has small lateral dimensions, the second interconnect is reliably connected to the third interconnect arranged above it. In this context, use is made of the fact that the height, i.e., the extent measured perpendicular to the substrate surface, of a parasitic contact structure is largely independent of the intensity of a diffraction-related ancillary maximum for lithographic exposure, whereas the width, i.e., the dimension of parasitic contact structures in a direction parallel to the substrate surface, varies greatly with the intensity of interfering ancillary maxima.

The inventive arrangement means that contact with a parasitic contact structure, if one is present between the two contact elements, is made from the bottom and from the top instead of from the side. This means that there is also a high probability of being able to detect parasitic contact structures with comparatively small lateral extents electrically. At the bottom, the parasitic contact structure makes contact with the second interconnect; at the top, it makes contact with the third interconnect. In particular, it is possible to detect parasitic contact structures that are narrower in the lateral direction than contact elements that conductively connect the first interconnects to the third interconnect.

Preferably, provision is made for the contact elements to be arranged in an insulating plane between the first and second interconnect planes and for the third interconnect to cover regions of the insulating plane, which are arranged between the contact elements and in which there is increased probability of parasitic contact elements being formed. Those regions of the insulating layer arranged between the two interconnect planes in which there is an increased probability of expectation of parasitic contact structures being formed are usually situated in the center between adjacent contact elements that are arranged on the first interconnects on both sides of the second interconnect.

Preferably, provision is made for the contact elements to be arranged on the first interconnects such that parasitic contact structures, which may arise as a result of interference effects between adjacent contact elements, make contact with the second interconnect. This is achieved most simply through symmetrical arrangement of the contact elements on the first two interconnects. In this context, one or more contact elements are arranged on one of the two first interconnects. Arranged in mirror-image symmetrical fashion with respect thereto in relation to the second interconnect are further contact elements on the other of the two first interconnects at identical positions in the direction of the path of the first interconnects.

Preferably, provision is made for the second interconnect to be arranged relative to the two first interconnects such that parasitic contact structures, which are formed on account of interference effects, are arranged centrally on the second interconnect.

Provision is likewise preferably made for the first interconnects to be arranged on opposite sides of the second interconnect at the same respective distance from the second interconnect.

Provision is preferably made for the third interconnect in the second interconnect plane to be shaped such that parasitic contact structures, which are formed on account of interference effects between the contact elements, make contact with the third interconnect. To this end, the third interconnect in the second interconnect plane is routed via those regions of the underlying insulating layer on which there is increased expectation of parasitic contact structures being formed.

Provision is preferably made that in the region of an interconnect section in which the first interconnects run parallel to one another, the third interconnect also covers the second interconnect and interspaces between the second interconnect and the two first interconnects. In this case, covering means that in the plan view perpendicularly on to the semiconductor wafer the base area of the third interconnect intersects the base areas of the two first interconnects and of the second interconnect and also extends over the interspaces between the second and the two first interconnects. In the simplest case, the third interconnect runs over the first and second interconnects perpendicular to the path thereof. In this case, first of all the insulating plane with the insulating layer and the contact elements made therein and possibly also parasitic contact structures are arranged directly below the third interconnect, and then the first and second interconnects run below these. The third interconnect, therefore, does not cover the surface of the first and second interconnects directly, but rather is spaced apart from them in a direction perpendicular to the substrate surface.

Provision is preferably made for the third interconnect to run transverse to the path of the first interconnects and of the second interconnect. This provides a simple way of ensuring that any parasitic contact structures that are formed make contact with the underside of the third interconnect. At least when there is a sufficient width of third interconnect in the direction of the path of the first and second interconnects there is the assurance of full contact being made with the top side of parasitic contact structures by the underside of the third interconnect.

In one development of the invention, each of the two first interconnects has at least two contact elements arranged on it that are arranged at a plurality of positions along the path of the first interconnects, with their positions on the two first interconnects being mirror-inverted with respect to one another in relation to the second interconnects. In this context, the positions of the total of at least four contact elements can be associated with the comers of a rectangle whose center is located centrally over the second interconnects. With an appropriate arrangement of contact openings in the lithographic mask (reticle), interference maxima and parasitic contact structures formed as a result are then produced in the center between the four contact elements, i.e., centrally over the second interconnect.

Provision is preferably made for the third interconnect to cover an interspace between four contact elements completely.

To this end, provision may be made, by way of example, for the third interconnect to have a width that is at least as great as the sum of the distance between two contact elements arranged on a first interconnect and twice the width of a contact element. The third interconnect running transverse to the first interconnects is thus wide enough to ensure that contact is safely made with the entire top side of a parasitic contact structure if the latter is formed somewhere between the four surrounding contact elements.

Provision is preferably made for the contact elements to be contact hole fillers. Contact hole fillers, also called “vias”, are made in openings in an insulating layer that is arranged between adjacent interconnect planes. The lithographic resolution limit for patterning the insulating plane may also correspond to or be greater than the resolution limit of the underlying first interconnect plane. By contrast, the second interconnect plane normally has an even greater lithographic resolution limit. In the present application, it is assumed that the terms “interconnect plane” and “insulating plane” mean technological layer planes within the meaning of semiconductor technology. These planes are represented by corresponding layer strata which, in contrast to a mathematical plane, have a certain layer thickness and also have the topographies, i.e., level differences, which are usual for semiconductor circuits.

In addition, each interconnect or insulating plane normally contains at least two different materials in order to produce patterning in a lateral direction in the form of standard contacts or interconnects. The interconnect planes contain interconnects and insulating regions. The insulating planes contain connecting contact elements (vias) perpendicularly in the direction of the substrate surface, and possibly also parasitic contact structures that have been formed. These are respectively surrounded by insulating material. The contact elements are normally formed by virtue of an initially deposited insulating layer that covers the entire area of the semiconductor substrate or the last deposited plane being covered with a resist layer, and the resist layer being exposed through a lithographic mask.

When positive resist is used the exposed regions of the resist layer are etched. When the exposed regions of the resist layer have been removed by an etching process and the resist layer has been cured, the insulating layer is etched using the patterned resist layer as an etching mask, which produces contact hole openings in the insulating layer that extend down to the underlying layer. If, following removal of the resist layer, a conductive material is deposited over the entire area and is then removed from the top side of the insulating layer again then electrically conductive contact hole fillers, namely the desired contact elements, remain in the contact hole openings in the insulating layer. The positions of the contact elements that have been placed correspond to the positions of mask openings in the lithographic mask (reticle) that has been used in the beam path of the lithographic exposure device at a distance from the semiconductor wafer in order to pattern the resist layer.

The undiffracted components of the electromagnetic radiation that pass through the mask openings expose the resist mask at the points at which the contact elements are to be formed. Undesirable diffracted radiation components can also expose the resist layer at the sides outside of the maps of the mask openings, however, specifically particularly at points at which diffraction maxima from a plurality of mask openings arranged closely together interfere constructively with one another. When the wanted contact elements are being produced, this simultaneously results in additional contact hole openings, possibly of smaller dimensions, and, after the conductive material has been deposited into these additional contact hole openings, undesirable parasitic contact structures.

In one development, the test structure has a multiplicity of first interconnects and a multiplicity of second interconnects that run parallel to one another, with a first interconnect and a second interconnect respectively being arranged alternately in succession in a direction transverse to the interconnect path. In this way, if each first interconnect is covered by one or more respective contact elements, a parasitic contact structure should be produced at a multiplicity of positions centrally on one of the second interconnects, the parasitic contact structure being electrically detected by the inventive test structure. The increase in the number of interconnects increases the probability of such a parasitic contact structure being formed anywhere on one of the second interconnects and resulting in a short circuit between a first and the third interconnect.

Provision is preferably made for the first interconnects to be jointly connected to a first connecting line and for the second interconnects to be jointly connected to a second connecting line within the first interconnect plane. This means that is suffices to provide just a single contact for all the first interconnects and just a single contact for all the second interconnects. A needle card placed onto the test structure from the outside thus requires just two additional test needles for the inventive measurement operation, the test needles actuating a multiplicity of first and second lines. Instead of the first lines, it is also possible to connect one or more third lines, which run in the second interconnect plane and preferably cross the first and second interconnects.

Provision is preferably made for the first interconnects and the second interconnects to be arranged so as to engage in one another in combed fashion. This allows the contact points for all the first and second interconnects to be provided in space-saving fashion and efficiently on opposite sides of the test structure.

Provision is preferably made for the test structure to be arranged in the region of a saw frame of the semiconductor wafer.

In one development, the second interconnect plane contains a plurality of third lines, with each of the third interconnects respectively covering a multiplicity of shorted first interconnects and a multiplicity of shorted second interconnects, which are arranged between the respective first interconnects. This means that there are a plurality of third interconnects that run transversely over the first and second interconnects and above them. Each of these third lines is connected to another multiplicity of first interconnects by contact elements. The multiplicity of third lines is used to form a matrix-like array of a large number of crossing locations between third and second interconnects, each crossing location potentially being able to have a parasitic contact structure that shorts the respective second line to the respective third line.

Provision is preferably made for the first, second and third interconnects and the contact elements to be arranged such that parasitic contact structures, which are formed on account of interference effects between the contact elements, conductively connect the second interconnects to the third interconnects in a direction perpendicular to the surface of the semiconductor wafer. Accordingly, the parasitic contact structures, if they are actually present, form a leakage current path that runs in a direction perpendicular to the surface of the semiconductor substrate and shorts a second interconnect arranged in the first interconnect plane to a third interconnect, running above the second interconnect, from the second interconnect plane. Even with a small lateral cross section for a parasitic contact structure, this results in a short circuit and can be detected because the inventively provided direction of the leakage current path runs perpendicular to the parasitic contact structures'width, which is critical for detection.

Preferably, the semiconductor wafer has an integrated semiconductor circuit with a memory cell array. The semiconductor circuit can include a plurality of fourth interconnects that run parallel to one another and that are arranged in the first interconnect plane and are at a distance from one another, which is as great as the distance between the second interconnect and the first interconnects of the test structure. A fifth interconnect is arranged in the second interconnect plane and runs in a direction transverse to the path of the fourth interconnects. Further contact elements electrically connect the fourth interconnects, which are at least next but one to one another, to the fifth interconnect.

In this embodiment, the interconnects in the memory cell array of an integrated semiconductor circuit run in the same technological planes as the interconnects of the inventive test structure, which is arranged outside of the memory circuit in the region of the saw frame. In the present application, the technological planes are called “first interconnect plane” and “second interconnect plane,” these names needing to be understood only for the purposes of enumeration. In particular, “first interconnect plane” and “second interconnect plane” do not necessarily denote the bottommost two interconnect planes above the substrate surface, but rather denote any two interconnect planes that are separated from one another by one or more insulating planes. Preferably, the second interconnect plane is arranged at a greater distance from the substrate surface than the first interconnect plane. The first interconnect plane and the substrate surface may also have further interconnect planes provided between them. In the embodiment above, the first and second interconnects in the test structure are arranged in the same interconnect plane as the fourth interconnects in the memory cell array of the semiconductor circuit. In addition, the third interconnects in the test structure are arranged in the same interconnect plane as the fifth interconnects in the memory cell array. This can be seen, by way of example, from the fact that the interconnects arranged in the same planes are made of the same material and have the same feature size.

In another embodiment, the invention provides a method for detecting parasitic contact structures on a semiconductor wafer with a test structure. At least two first interconnects are arranged in a first interconnect plane and run parallel to one another at least in sections. At least one second interconnect is arranged between the two first interconnects and runs parallel to the first interconnects. A third interconnect runs in a second interconnect plane, which is arranged at a greater distance from a surface of the semiconductor wafer than the first interconnect plane. At least one respective contact element is provided on each of the two first interconnects, the contact element electrically conductively connects the respective first interconnect to the third interconnect. The second interconnect is connected to a first electrical potential and the third interconnect is connected to a different, second electrical potential. An electrical resistance or current measurement is performed, which measures whether the third interconnect is conductively connected to the second interconnect.

For this measurement method, it is particularly possible to use any semiconductor wafer whose test structure or test structures is/are designed in accordance with one of the previously described embodiments.

Preferably, if a measured electrical resistance is below a prescribed limit value, or a measured current level is above a prescribed limit value, then it is established that the second interconnect and the third interconnect are shorted together by a parasitic contact structure, and otherwise it is established that no parasitic contact structure is present between the second interconnect and the third interconnect. On the basis of the geometry chosen in accordance with the invention, where any parasitic contact structures formed adjoin neighboring conductive structures at the bottom and at the top instead of in a lateral direction in relation to the substrate surface, there is the assurance that the electrical measurement here has a high probability of detecting any parasitic contact structures that are present.

Preferably, a semiconductor wafer is used which, apart from the test structure, has at least one integrated semiconductor circuit, and a measurement result obtained using the test structure is used for quality control for the integrated semiconductor circuit.

In particular, there may be provision that, if it is established for at least one test structure that the respective test structure has at least one parasitic contact structure, then the integrated semiconductor circuit arranged on the semiconductor wafer is marked as being not perfectly operable. Since the test structure and the memory cell array in the integrated semiconductor circuit are produced from the same technological planes, particularly interconnect planes and insulating planes, the measurement result obtained using the test structure can be used with a high level of reliability to a further degree of operability of the integrated memory circuit.

Provision is preferably made that on a semiconductor wafer that has a multiplicity of test structures, steps are performed on the multiplicity of test structures, with a separate resistance or current measurement being performed for each test structure. The measurements can be performed on the test structures in order or else can be performed on them simultaneously. In the latter case, a larger number of additional test needles is required.

Finally, provision may be made for the second interconnects of the multiplicity of test structures to be electrically connected to one another and to be biased with the same respective first electrical potential, and for the third interconnects on the test structures to be respectively connected to the second electrical potential. In this context, it is not just all the second interconnects in a multiplicity of test structures that are permanently shorted together in this way, so that they can be jointly biased by a single electrical connection. When the electrical measurement is performed, only the third or first lines then need to be biased relative to the second lines.

### BRIEF DESCRIPTION OF THE DRAWINGS

The invention is described below with reference to the figures, in which:

FIG. 1 shows a schematic plan view of a semiconductor wafer;

FIG. 2 shows a schematic illustration of a lithographic mask and of a lithographically exposed mask layer;

FIG. 3 shows a schematic cross-sectional view of a semiconductor wafer with an inventive test structure;

FIG. 4 shows a schematic plan view of the test structure from FIG. 3;

FIG. 5 shows a further embodiment of the inventive test structure in a schematic plan view;

FIG. 6 shows a schematic cross-section through two regions of a semiconductor wafer, which represent a detail from an inventive test structure and from a memory cell array;

FIG. 7 shows a plurality of interconnected inventive test structures;

FIG. 8 shows a schematic illustration of an inventive method; and

FIG. 9 shows a flowchart for the timing of an inventive method.

The following list of reference symbols can be used in conjunction with the figures:
1 First interconnect 30 Semiconductor circuit
2 Second interconnect 31 Fourth interconnect
3; 3a, 3b, 3c Third interconnect 33 Fifth interconnect
4; 4a, . . . , 4d Contact element 34 Further contact element
5 Parasitic contact structure 35 Memory cell array
6 Insulating layer A First interconnect plane
9 Interconnect section B Second interconnect plane
10 Semiconductor wafer C Insulating plane
10a Surface CD Feature size
11 First connecting line I Current level
12 Second connecting line I0 Prescribed limit value for the current level
15 Saw frame or kerf Ω Ohmic resistance
16 Mask layer Ω0 Prescribed limit value for the ohmic resistance
20 Test structure V1 First potential
21 Mask V2 Second potential
22 Mask opening x, y, z Directions

### DETAILED DESCRIPTION OF ILLUSTRATIVE EMBODIMENTS

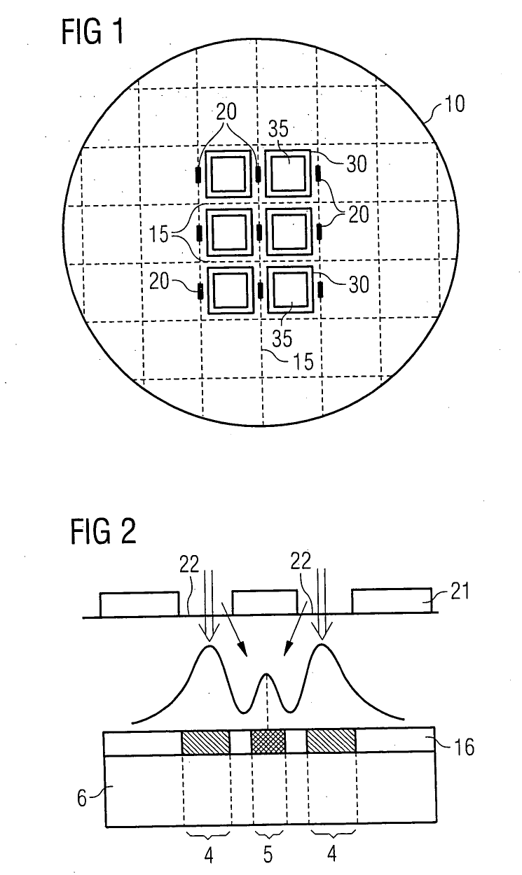

FIG. 1 shows a schematic plan view of a semiconductor wafer 10 on which a multiplicity of integrated semiconductor circuits 30 are arranged. By way of example, the semiconductor circuits 30 may be memory circuits, for example circuits for volatile or non-volatile semiconductor memories. Each integrated semiconductor circuit 30 has a memory cell array 35 in which memory cells are arranged in the form of a two-dimensional matrix and are connected in two directions by interconnects, namely by word lines and bit lines. The internal design of the memory cell array 35 is known and is, therefore, not illustrated in more detail.

Between the integrated semiconductor circuits 30 there is the saw frame 15 (“kerf”) for the semiconductor wafer 10, which surrounds each semiconductor circuit 30 individually and which is removed when the semiconductor wafer 10 is split. In this case, the semiconductor wafer 10 is sawn up along the line shown in dashes, which destroys the saw frame 15.

FIG. 1 shows a plurality of test structures 20 that are arranged in the region of the saw frame 15. Such test structures 20 are conventionally used for different purposes. The test structures 20 partly reproduce the integrated circuit design of a memory cell array 35 so as to be able to perform measurements in the region of the saw frame 15 before the semiconductor wafer 10 is split, the measurements not being able to be performed on the memory cell array 35 itself, or at least not nondestructively.

The test structures 20 within a saw frame 15 can be used, inter alia, to detect the formation of any parasitic contact structures within wiring planes. Parasitic contact structures are produced, inter alia, by interference effects during lithographic exposure, in which a mask layer deposited on or above the semiconductor wafer 10 is first of all exposed. The mask layer is then patterned and the pattern of the mask layer is transferred to the layer that is to be patterned, which is arranged beneath it. This produces layer openings into which a conductive material can be deposited, for example. This produces contact elements, in particular, such as the standard contacts in the form of vias.

FIG. 2 schematically shows a cross-section through an insulating layer 6, which is to be patterned, a mask layer 16 arranged thereon and through a lithographic mask 21. The mask 21 (“reticle”) has mask openings 22 through which electromagnetic radiation can penetrate, as illustrated by the arrows. The largest component of the intensity of the radiation passes undiffracted, i.e., essentially rectilinearly, through the openings in the lithographic mask 21 and selectively exposes individual regions of a mask layer 16. The insulating layer 6 may be an insulating layer that is arranged between two interconnect planes A, B, for example, and which is selectively exposed in regions in order to produce contact elements 4. The contact elements 4 are produced by virtue of the exposed regions of the patterned mask layer 16 being removed by etching and the insulating layer 6 beneath the patterned mask layer 16 being etched, for example. The resultant contact holes in the insulating layer 6 are then filled with a conductive material. The lateral positions of the contact elements 4 formed in this manner correspond to the positions of the mask openings 22 in the lithographic mask 21. Since a certain component of the electromagnetic radiation is diffracted and can interfere constructively between adjacent mask openings 22, however, unwanted intensity maxima beneath regions of the mask 21 that are impermeable to radiation result in undesirable parasitic contact structures 5. The parasitic contact structures 5 have no correspondence to the lithographic mask 21. Within the multilayer wiring on a semiconductor wafer, parasitic contact structures 5 can result in leakage current paths by shorting together adjacent interconnects. This makes the respective semiconductor circuit unusable at least in subregions. Depending on how the process parameters are selected for producing the integrated lithographic exposure for forming the contact elements 4, there is a more or less great probability of parasitic contact structures 5 being additionally formed between adjacent contact elements 4.

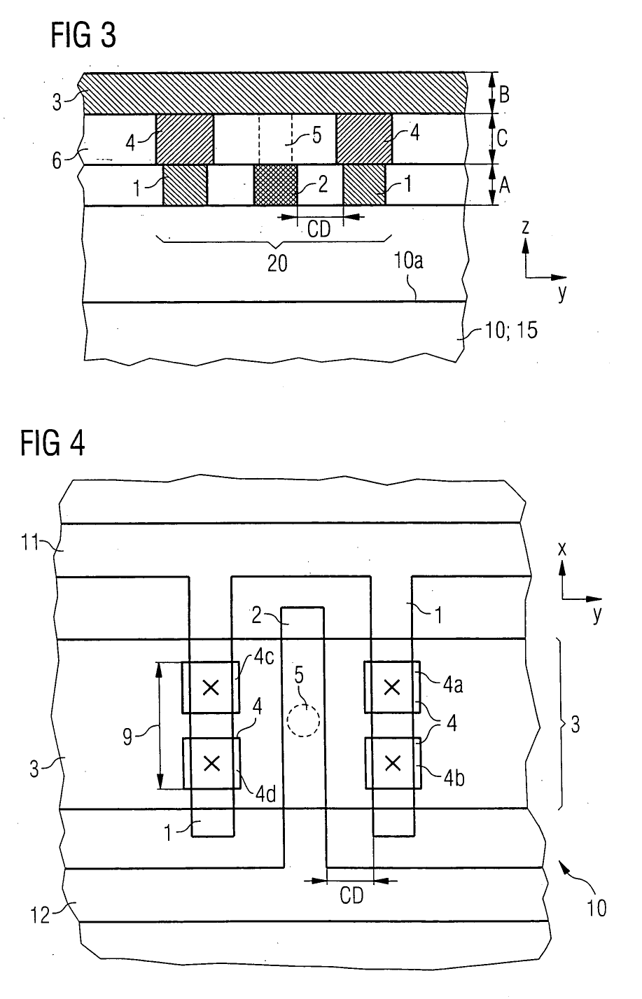

FIG. 3 shows an inventive test structure 20 that is used to detect such parasitic contact structures 5 and that achieves a very high level of detection probability. The inventive test structure 20 is arranged in the region of a saw frame in a semiconductor wafer 10. FIG. 3 shows a cross-section in a direction z perpendicular to the substrate surface 10a. Above the substrate surface 10a there runs a first interconnect plane A in which interconnects 1, 2 are arranged. Arranged at a greater distance from the surface 10a of the semiconductor wafer 10 is a third interconnect 3 in a second interconnect plane B. The interconnect planes A and B correspond to those interconnect planes that are also provided in the region of a memory cell array in an integrated semiconductor circuit on the semiconductor wafer 10, so that mutually corresponding structure elements, such as interconnects or vias, are simultaneously present in the semiconductor circuits 30 and in the test structure 20 on the saw frame. The lithographic masks required for this purpose contain both mask openings for producing the structure elements of the memory cell array and structures for producing the inventive test structures 20.

The inventive test structure has two first interconnects 1 that are arranged in the first interconnect plane A and that run parallel to one another at least in sections. In FIG. 3, the first interconnects 1 run perpendicular to the plane of the drawing. The first interconnect plane A also contains a second interconnect 2 that is arranged between the two first interconnects 1 and that runs parallel to them. FIG. 3, therefore, shows the interconnect cross-sections of the first interconnects 1 and of the second interconnect 2. The inventive test structure 20 also has a third interconnect 3 that runs in the second interconnect plane B. In FIG. 3, the interconnect 3 runs parallel to the plane of the drawing and crosses the first interconnects 1 and the second interconnect above the first interconnect plane A. Finally, the inventive test structure has at least one contact element 4 on each first interconnect 1, the contact element 4 connecting the respective first interconnect 1 to the third interconnect 3. This shorts the first interconnects 1 to the third interconnect 3. The contact elements 4 are arranged in an insulating plane C between the two interconnect planes A, B.

The lateral distance between the second 2 and a first 1 interconnect corresponds to the smallest possible lithographically achievable feature size CD, which is achieved in the interconnect plane A when the prescribed exposure wavelength is used.

The invention provides a semiconductor wafer 10 (or another substrate) having a test structure 20 whose interconnects 1, 2 and 3 running above and below contact elements 4 are arranged such that if parasitic contact structures 5 appear between the contact elements 4 there is an electrically conductive leakage current connection between the second and third lines that is able to be detected by an electrical measurement. The mirror-image symmetrical arrangement of the contact elements 4 relative to the second interconnect 2 means that parasitic contact structures 5 are expected to appear precisely in the center on the second interconnect 2, preferably with a diagonal offset between four surrounding contact elements 4 in the lateral direction, as will be explained below by FIG. 4. Normally, parasitic contact structures that have smaller dimensions in the lateral direction than the contact elements 4 cannot be detected reliably, since they result in a leakage current path between two passing interconnects only if they are of sufficient size. However, the inventive test structure 20 is designed such that parasitic contact structures 5 are detected with a very high level of probability even if their width is small. In the case of the inventive test structure 20, a conductive connection is set up between two interconnects 1, 2 running in the same interconnect plane A, with any parasitic contact structures 5 closing the leakage current path not in a direction parallel to the first interconnect plane A but rather in a direction perpendicular to it. This is achieved by virtue of the first interconnects being connected to the third interconnect via the contact elements 4, and by virtue of the third interconnect 3 running over those regions of the insulating plane C at which there is the greatest expectation of parasitic contact structures 5 appearing.

In addition, below such a region of increased probability of parasitic contact elements 5 appearing there is an interconnect arranged opposite, namely the second interconnect 2, which is conductively connected to the first interconnects 2 via the third interconnect only if a parasitic contact structure 5 has been formed above it. Since the parasitic test structure 5, if present, usually extends over the entire layer thickness of the insulating layer C even when the width is small, there is the assurance that the parasitic contact structure 5 has a high probability of shorting the second interconnect 2 running below it to the third interconnect 3 running above it (and hence also to the first interconnects 1). If electrical potentials at different levels are applied to corresponding supply lines either for the second 2 and the third 3 interconnect (or for the second 2 and a first 1 interconnect) then at precisely that time a current flows through the inventive test structure 20 if a parasitic contact structure 5 has been formed between the second 2 and the third 3 line. If there is no parasitic contact structure formed between the second 2 and the third 3 interconnect, there is no or just a high-impedance electrical connection between them. This means that by making contact with the inventive test structure 20 (for example using test needles on a needle card) it is possible to determine whether there is the risk of parasitic contact structures 5 between the interconnect planes A and B in the memory cell array of an integrated semiconductor circuit too.

FIG. 4 shows a schematic plan view of the inventive test structure from FIG. 3. The plan view corresponds to the plan view of an area parallel to the surface 10a of the semiconductor substrate 10. The two first interconnects 1 run parallel to one another, at least along an interconnect section 9. In addition, the second interconnect 2 in the same interconnect plane A runs between the two first interconnects 1 and parallel to them. In the higher-placed second interconnect plane B, the third interconnect 3 runs. In FIGS. 3 and 4, it runs transverse to the path of the first 1 and second 2 interconnects. An insulating layer 6, which is arranged between the two interconnect planes A, B, contains the contact elements 4 that short the first interconnects 1 to the third interconnect 3, as identified by crosses in FIG. 4. In particular, FIG. 4 shows that the inventive test structure 20 can have four contact elements 4a, 4b, 4c, 4d, in the center of which there is an increased probability of a parasitic contact structure 5 being formed. The region of the insulating layer 6 at which this probability is particularly high is completely covered by the third interconnect 3. If a parasitic contact structure 5 has been formed in the center between the two or, as FIG. 4 shows, four contact elements 4, then the parasitic contact structure 5 connects the second interconnect 2 running below it to the third interconnect 3 running above it largely independently of its width. This allows the contact structure 5 to be detected particularly reliably. To detect it, different electrical potentials are applied to the second and third lines 2, 3 and the current or the resistance between the two potentials is measured.

FIG. 5 shows a development of an inventive test structure 20 in which a multiplicity of first interconnects 1 and second interconnects 2 are provided. The first and second interconnects 1, 2 engage in one another in combed fashion. Each first interconnect 1 is covered by two contact elements 4, alternatively, more than two contact elements 4 may also be arranged on each first interconnect 1. By contrast, the second interconnects 2 have no contact elements 4 arranged on them. However, if interference from diffracted radiation components during lithographic exposure of the mask layer and transfer of its structure to the insulating layer that is to be patterned means that parasitic contact structures 5 are formed, these are arranged centrally on the second interconnects 2.

The first interconnects 1 are connected jointly to a first connecting line 11, and the second interconnects 2 are connected jointly to a second connecting line 12. In addition, the first interconnects 1 are connected via the contact elements 4 to the third line 3 arranged in the upper, second interconnect plane B. Precisely at that point there is a flow of current from the second connecting line 12 to the first connecting line 11 (or else from the second connecting line 12 to the third line 3) if the second interconnect 2 is shorted to the third interconnect 3 by a parasitic contact structure 5. The plurality of second lines 2 in FIG. 5 means that there is an increased probability (in comparison with the embodiment in FIGS. 3 and 4) of a parasitic contact structure 5 having been formed somewhere within the test structure 20 and, therefore, of an electrical short circuit arising between a second interconnect 2 and a third interconnect 3. This means that the probability of detection of parasitic contact structures is also increased to an even greater extent.

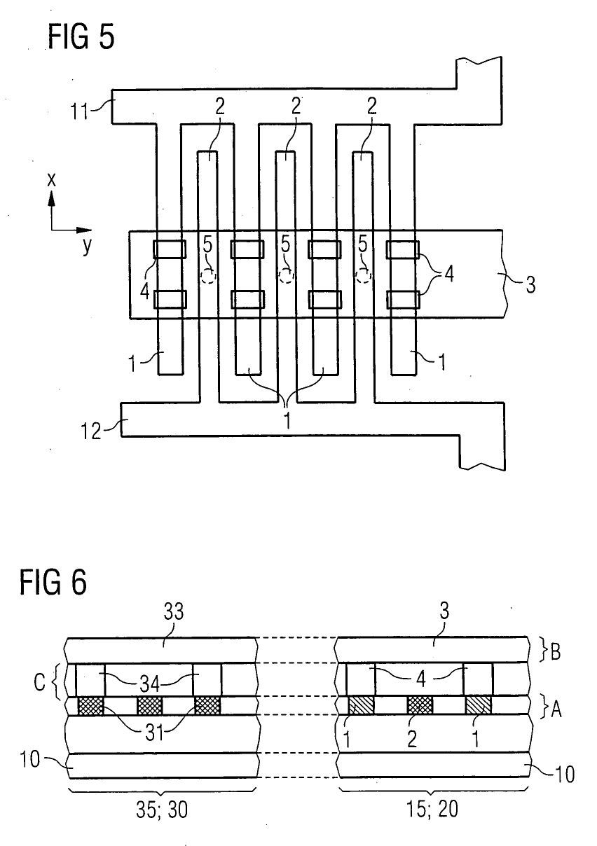

FIG. 6 shows a cross-section through two different sections of one and the same semiconductor wafer 10. The left-hand section is a portion of a memory cell array 35 that is part of an integrated semiconductor circuit 30 that, following splitting of the semiconductor wafer 10, is maintained as a chip and represents the actual semiconductor product. The right-hand section of the semiconductor wafer 10 shows an inventive test structure 20 that is arranged in the region of the saw frame 15 of the semiconductor wafer. As shown by the dashed lines, both the region of the memory cell array 35 and the region of the test structure 20 have the same technological planes running in them, namely the first interconnect plane A, the insulating plane C arranged above that and the second interconnect plane B arranged above that. Arranged in the region of the test structure 20, as described above, are the first, second and third lines 1, 2, 3 and the contact elements 4. In the region of the memory cell array 35, the first interconnect plane A has fourth lines 31 running in it, which were produced at the same time as the first and second interconnects 1, 2 and were, therefore, produced from the same material composition and using the same feature size, and with identical process parameters being set. In addition, the fifth lines 33 are produced together with the third lines 3 and run in the same interconnect plane B. Furthermore, further contact elements 34, which connect the fourth lines 31 to the fifth lines 33 are produced at the same time as the contact elements 4 of the test structure. In the memory cell array 35, the electrical connections of the fourth lines 31 and fifth lines 33 to the memory cells that are to be arranged in the substrate 10 are not shown. However, it is possible to see from the technological planes A, B and C that parasitic contact structures may also be produced in the memory cell array 35, in a similar manner to the contact structures 5 in the test structure 20 from FIG. 5. In such a case, however, these parasitic contact structures are produced both in the memory cell array 35 and in the test structure 20. In the test structure, a parasitic contact structure can then be detected using an electrical test before the semiconductor wafer 10 is split.

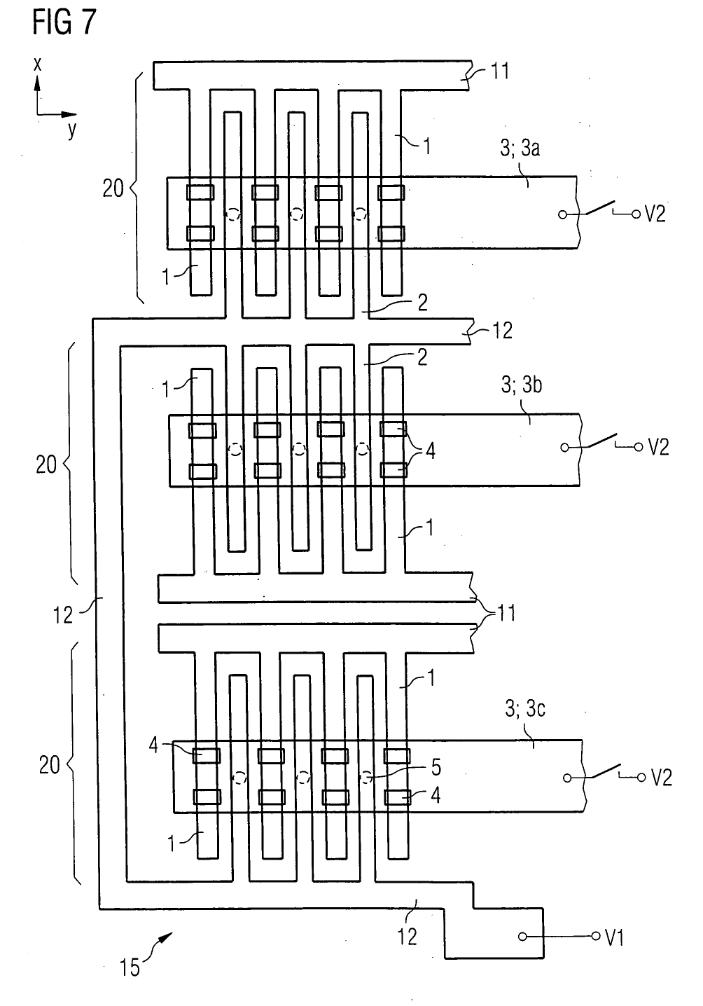

FIG. 7 shows a plurality of inventive test structures 20 whose second lines 2 are jointly connected to the second connecting line 12. A total of three third lines 3 are shown, namely the lines 3a, 3b and 3c, which can also be used to detect any parasitic contact structures 5 that are present in a second lateral direction x at various positions on the semiconductor wafer, for example, in order to indicate a locally concentrated occurrence of leakage current paths when production conditions are inhomogeneous over the substrate surface. In FIG. 7, the three test structures 20 shown each have a multiplicity of first lines 1 and second lines 2. For each test structure 20, the respective third interconnect 3 is shorted to the first interconnects 1 by contact elements 4. However, there is no electrical connection to the first 1 and third 3 interconnects and the remaining test structures. Such a connection is also not produced if parasitic contact structures 5 are present; however, these result in a short circuit between the second 2 and the third 3 interconnect within the same test structure 20.

Each third interconnect 3a, 3b, 3c can be connected individually to a second potential V2, which differs from a first potential VI, which is used to bias all second lines 2. As a result of the voltage difference, a leakage current is obtained in a test structure 20 precisely when at least one parasitic contact element 5 is formed in the relevant test structure 20 on one of the second interconnects 2. Since the various third interconnects 3a, 3b, 3c are not shorted together, it is possible to locate those positions in the direction x on the saw frame 15 at which parasitic contact structures 5 appear. With regard to the size of today's semiconductor wafers 10 of up to 20 or 30 cm, the test data obtained in the saw frame region 15 can be used to obtain statements about any concentrations of parasitic contact structures 5 in subregions of the wafer area.

In FIG. 7, the third lines 3a, 3b, 3c in the plurality of test structures 20 can optionally be biased simultaneously using the second potential V2. Alternatively, they can be biased successively using the second potential V2. In the latter case it may be possible to refuse the number of contact needles required on a contact head that is to be put on.

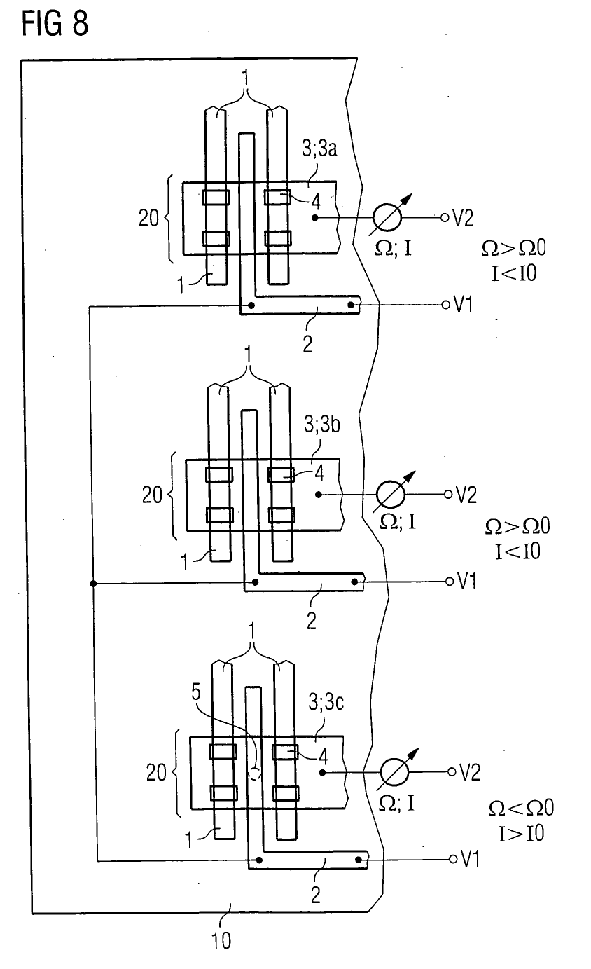

FIG. 8 shows a schematic illustration of an inventive method for detecting parasitic contact structures on a semiconductor wafer. FIG. 8 shows a detail from the semiconductor wafer 10 in which three test structures 20 corresponding to one another have been formed. As described above, each test structure respectively has at least two first lines 1, at least one second line 2, arranged in the same interconnect plane as the first line, and a third line 3 arranged above the first and second lines. The third lines 3 are in turn connected to the first interconnects 1 by contact elements 4. The second lines 2 of all three test structures 20 are shorted together, which means that when one of the second lines 2 is biased with the first potential VI, all the other second lines are biased using the same first potential VI.

An electrical measurement, preferably a current measurement or a resistance measurement, is performed on each test structure 20, with the current level I of a current that flows between the respective third line 3 and the respective second line 2 or the ohmic resistance Ω between the respective third line 3 and the respective second line 2 being measured. In the topmost test structure 20 shown in FIG. 8, the second interconnect 2 and the third line 3 running above it have no parasitic contact structure formed between them in the insulating layer in which the contact elements 4 are arranged. The third line 3a in the topmost test structure 20 is, therefore, not conductively connected to the second line 2 in this test structure. The current level I measured is, therefore, below a prescribed limit value I0 for the current level, or the measured ohmic resistance Ω is above a prescribed limit value Ω0. This means that at least in the region of the upper test structure 20 the lithographic production of the contact elements 4 has not resulted in the formation of parasitic contact structures. The same measurement result is obtained for the middle test structure 20 shown in FIG. 8. For the bottommost test structure 20 in FIG. 8, however, the electrical measurement results in the measured ohmic resistance Ω being smaller than the prescribed limit value Ω0 for the resistance or in the measured current level I being greater than the prescribed limit value I0 for the current level. This makes it possible to infer that between the second interconnect 2 and the third line 3c in the bottommost test structure 20 from FIG. 8, a parasitic contact structure 5 has been formed between the adjacent contact elements 4, as shown at the bottom in FIG. 8. Since a parasitic contact structure has thus been detected for at least one of the test structures 20, it can be expected that integrated semiconductor circuits 30 arranged on the same semiconductor wafer 10 that have a memory cell array 35 with interconnects running in the same interconnect planes may likewise contain parasitic contact structures. Therefore, all or at least some of the semiconductor circuits 30 that are arranged in the surroundings of the test structure 20 shorted by the parasitic contact structure 5 are marked as being inoperable and are discarded when the semiconductor wafer 10 has been split.

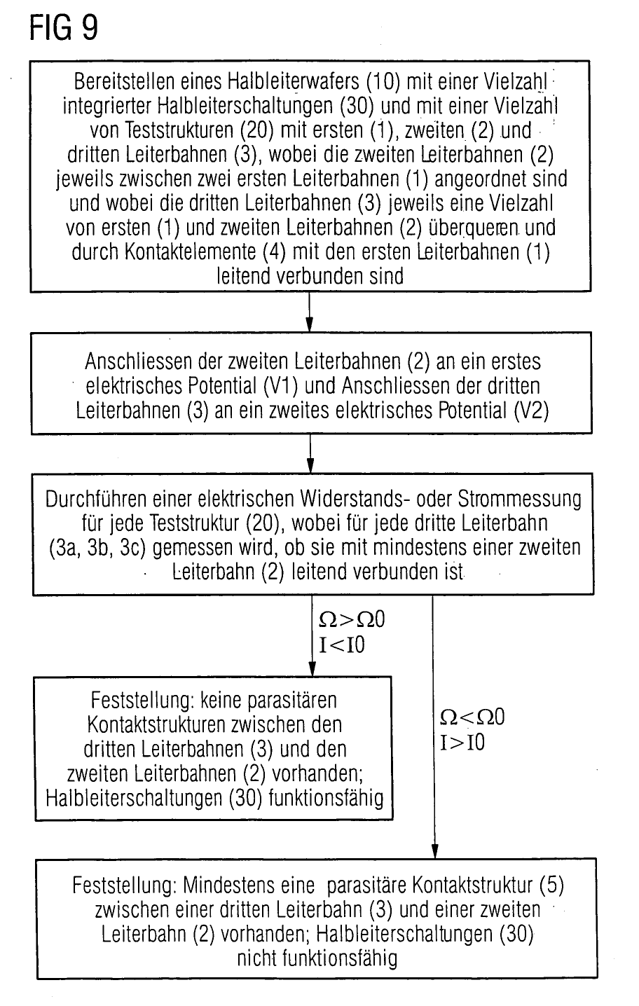

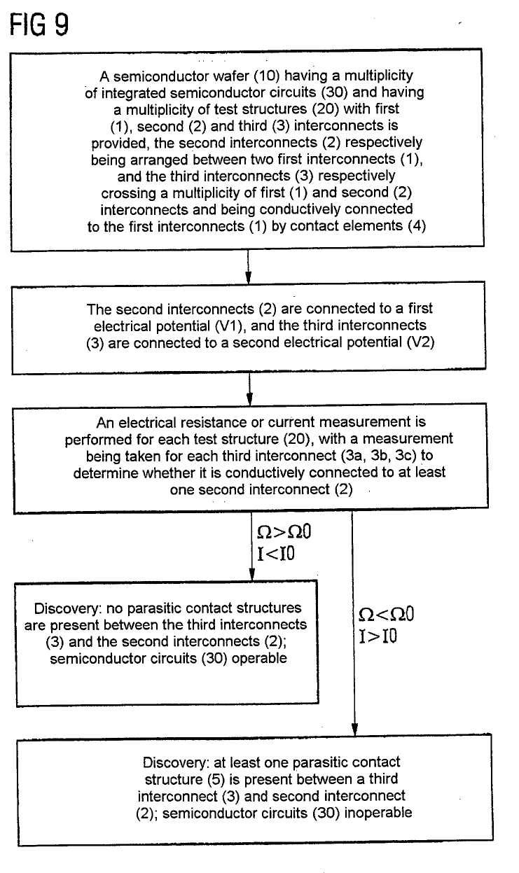

FIG. 9 shows a schematic flowchart of a method based on embodiments of the invention. First, a semiconductor wafer 10 having a multiplicity of integrated semiconductor circuits 30 and a multiplicity of test structures 20 with first, second and third interconnects 1, 2, 3 is provided, in which each second interconnect 2 is arranged between two respective first interconnects 1 and in which the third interconnects 3 respectively cross a multiplicity of first and second interconnects 1, 2 and are electrically connected to the first interconnects 1 by contact elements 4. To carry out the method, the second interconnects 2 are connected to a first electrical potential V1, and the third interconnects 3 are connected to a different, second electrical potential V2. This can be done, by way of example, by virtue of the electrical function test on the integrated semiconductor circuits 30 involving a contact head, for example a needle card with test needles, being put on, which, in the region of the saw frame of the semiconductor wafer, has additional test needles that make contact with the inventive test structures 20. When the test needles have been put on, an electrical measurement, a resistance measurement or a current measurement is performed, specifically on each individual test structure 20. This involves measuring for each of the third interconnects 3 whether the respect third interconnect 3a, 3b, 3c is conductively connected to at least one of the second interconnects 2. If the result of the measurement is that the ohmic resistance is above or the measured current level I is below a prescribed limit value, it is established that there are no parasitic contact structures between the third interconnects 3 and the second interconnects 2, and that the integrated semiconductor circuits 30 are, therefore, probably operable. However, if the result of the measurement is that the ohmic resistance on at least one test structure 20 is less than a prescribed maximum value or the electrical current level is greater than a prescribed minimum value, it is established that there is at least one parasitic contact structure 5 between one of the third interconnects 3 and the interconnects 2 that it crosses. Such a case is shown by way of example in the bottommost test structure 20 in FIG. 8. In this case, it is also established that all or some semiconductor circuits 30 are probably not operable. Test structures that are arranged in the region of the saw frame of the semiconductor wafer can thus be used to perform electrical measurements that cannot be performed nondestructively in the memory cell arrays 35 of the semiconductor circuits 30 themselves. The geometry of the test structures that is proposed in line with the embodiments of invention achieves a particularly high level of detection probability for any parasitic contact structures that are present.

Embodiments of the present invention make it possible, with a constant exposure wavelength from the lithographic exposure device but increasingly smaller dimensioned structures in integrated semiconductor circuits on account of undesirable ancillary maxima in the exposure intensity, which arise during lithographic exposure, to detect parasitic contact structures that have been produced with an increased detection probability. By way of example, it is possible to detect parasitic contact structures that appear in the insulating plane between the last two interconnect planes and that are not provided in the design of the integrated circuits. Side lobes that are produced during the production of vias and that appear as a result of constructive superimposition of the exposure intensities of adjacent contact elements can be reliably detected while observing the design rules for the semiconductor circuits. This allows reliable predictions about the operability of the semiconductor circuits to be obtained particularly for planes with a minimum feature size of 70 nm or below, without having to take measurements on the semiconductor circuits themselves. Instead, parasitic contact structures formed in the inventive test structures can be detected directly electrically. The detection thereof can be used to optimize the process and exposure parameters for the subsequent batches of semiconductor wafers in order to prevent further parasitic side lobes from appearing.

The interconnect planes in which the first, second and third lines are arranged may be, by way of example, the second interconnect plane from the bottom (also called M1 plane) and the third interconnect plane from the bottom (also called M2 plane), between which (in the “C2 plane”) the contact elements 4 need to be formed at a short distance from one another. The provision of an appropriate multiplicity of inventive test structures 20 on the semiconductor wafer 10 allows location-resolved measurement, for example through a matrix-like arrangement of a large number of test structures. A multiplicity of measurements on individual test structures 20 can be used to ascertain whether side lobes appear more at the edge or more in the center of the matrix-like arrangement of test structures, for example. The first interconnects may be used as support structures for optical proximity correction when the lower interconnect plane M1 is exposed. They can also be connected even using common connecting lines, in which case the second electrical potential is connected to the common connecting lines instead of to the third lines. In both cases, however, the measurement result is the same, since the first and third interconnects are permanently shorted together by the contact elements.

The inventive geometry of the test structures in which the leakage current path is produced by such parasitic contact structures as can be expected between the second and third interconnects, which cross one another, significantly increases the detection probability for such parasitic contact structures in comparison with conventional test structures.

What is claimed is:

1. A semiconductor wafer with a test structure, the semiconductor wafer comprising:
a substrate;
at least two first interconnects that are arranged in a first interconnect plane over the substrate and that include sections that run substantially parallel to one another at least in sections;
at least one second interconnect that is arranged in the first interconnect plane between the sections of the two first interconnects, the at least one second interconnect running substantially parallel to the sections of the first interconnects;
a third interconnect that runs in a second interconnect plane over the substrate, the second interconnect plane being arranged at a greater distance from a surface of the substrate than the first interconnect plane; and
at least one respective contact element on each of the two first interconnects, the contact element electrically connecting the respective first interconnect to the third interconnect, wherein the distance between the second interconnect and the two first interconnects corresponds to the lithographic resolution limit of the first interconnect plane; and
wherein the contact elements are arranged at positions being mirror-inverted with respect to one another in relation to the second interconnect running between the first interconnects.

2. The semiconductor wafer as claimed in claim 1, wherein the contact elements are arranged in an insulating plane between the first and the second interconnect plane and wherein the third interconnect covers regions of the insulating plane that are arranged between the contact elements.

3. The semiconductor wafer as claimed in claim 1, wherein the contact elements are arranged on the first interconnects such that parasitic contact structures, which may arise on account of interference effects between adjacent contact elements, make contact with the second interconnect.

4. The semiconductor wafer as claimed in claim 1, wherein the second interconnect is arranged relative to the two first interconnects such that parasitic contact structures, which may arise on account of interference effects between adjacent contact elements, are arranged centrally on the second interconnect.

5. The semiconductor wafer as claimed in claim 1, wherein the first interconnects are arranged on opposite sides of the second interconnect at a respective identical distance from the second interconnect.

6. The semiconductor wafer as claimed in claim 1, wherein the third interconnect in the second interconnect plane is shaped such that parasitic contact structures, which may arise on account of interference effects between adjacent contact elements, make contact with the third interconnect.

7. The semiconductor wafer as claimed in claim 1, wherein in the region of an interconnect section in which the first interconnects run parallel to one another, the third interconnect also covers the second interconnect arranged between the two first interconnects and also covers interspaces between the second interconnect and the two first interconnects.

8. The semiconductor wafer as claimed in claim 1, wherein the third interconnect runs transverse to the path of the first interconnects and of the second interconnect.

9. The semiconductor wafer as claimed in claim 1, wherein at least two contact elements are provided on each of the two interconnects, the contact elements being arranged at a plurality of positions along the path of the first interconnects, with their positions on the two first interconnects being mirror-inverted with respect to one another in relation to the second interconnect.

10. The semiconductor wafer as claimed in claim 1, wherein the third interconnect completely covers an interspace between four adjacent contact elements.

11. The semiconductor wafer as claimed in claim 1, wherein the third interconnect has a width that is at least as great as the sum of the distance between two contact elements arranged on a first interconnect and twice a width of a contact element.

12. The semiconductor wafer as claimed in claim 1, wherein the contact elements comprise contact hole fillings.

13. The semiconductor wafer as claimed in claim 1, wherein the test structure has a plurality of first interconnects and a plurality of second interconnects that run parallel to one another, the first interconnects and a second interconnects being arranged alternately in succession in a direction transverse to the interconnect path.

14. The semiconductor wafer as claimed in claim 13, wherein the first interconnects are jointly connected to a first connecting line and the second interconnects are jointly connected to a second connecting line.

15. The semiconductor wafer as claimed in claim 13, wherein the first interconnects and the second interconnects are arranged so as to engage in one another in combed fashion.

16. The semiconductor wafer as claimed in claim 1, wherein the test structure is arranged in a kerf of the semiconductor wafer.

17. The semiconductor wafer as claimed in claim 1, wherein the second interconnect plane contains a plurality of third interconnects, with each of the third interconnects respectively covering a plurality of first interconnects short-circuited with one another and a plurality of second interconnects short-circuited with one another arranged between the respective first interconnects.

18. The semiconductor wafer as claimed in claim 17, wherein the first, second and third interconnects and the contact elements are arranged such that parasitic contact structures, which may arise on account of interference effects between adjacent contact elements, conductively connect the second interconnects to the third interconnects in a direction perpendicular to the surface of the semiconductor wafer.

19. The semiconductor wafer as claimed in claim 1, wherein the semiconductor wafer has an integrated semiconductor circuit with a memory cell array, wherein the semiconductor circuit comprises:
a plurality of fourth interconnects that run parallel to one another and that are provided in the first interconnect plane and are arranged at a distance from one another that is as great as the distance between the second interconnect and the first interconnects of the test structure;
a fifth interconnect that is arranged in the second interconnect plane and that runs in a direction transverse to the path of that electrically connect the fourth interconnects.

20. A method for detecting parasitic contact structures on a semiconductor wafer with a test structure, the method comprising:
providing a test structure comprising:
at least two first interconnects that are arranged in a first interconnect plane, at least interconnect sections of the two first interconnects running parallel to one another;
at least one second interconnect that is arranged in the first interconnect plane between the two first interconnects and that runs parallel to the interconnect sections of the first interconnects;
a third interconnect that runs in a second interconnect plane that is arranged at a greater distance from a surface of the semiconductor wafer than the first interconnect plane; and
at least one respective contact element on each of the two first interconnects the contact element electrically conductively connecting the respective first interconnect to the third interconnect;
wherein the method comprises:
connecting the second interconnect to a first electrical potential and connecting the third interconnect to a different, second electrical potential; and
performing an electrical resistance or current measurement, thereby measuring whether the third interconnect is conductively connected to the second interconnect.

21. The method as claimed in claim 20, wherein if a measured electrical resistance is below a prescribed limit value or a measured current level is above a prescribed limit value then it is established that the second interconnect and the third interconnect are shorted together by a parasitic contact structure, and wherein otherwise it is established that no parasitic contact structure is present between the second interconnect and the third interconnect.

22. The method as claimed in claim 20, wherein the method is performed on a semiconductor wafer which, apart from the test structure, has at least one integrated semiconductor circuit, and wherein a measurement result obtained using the test structure is used for quality control for the integrated semiconductor circuit.

23. The method as claimed in claim 20, wherein if it is established for the test structure that the respective test structure has at least one parasitic contact structure then the integrated semiconductor circuit arranged on the semiconductor wafer is marked as being not perfectly operable.

24. The method as claimed in claim 20, wherein on a semiconductor wafer that has a plurality of test structures, the connecting and performing steps are performed on a plurality of test structures with a separate resistance or current measurement being performed for each test structure.

25. The method as claimed in claim 24, wherein the second interconnects of the plurality of test structures are electrically connected to one another and are biased with the same respective first electrical potential in the connecting step, and wherein the third interconnects on the test structures are respectively connected to the second electrical potential.
